(19) United States
(12) Patent Application Publication
(10) Pub. No.: US 2014/0269097 A1
(43) Pub. Date: Sep. 18, 2014

(54) NON-VOLATILE SEMICONDUCTOR MEMORY DEVICE AND METHOD OF CONTROLLING THE NON-VOLATILE SEMICONDUCTOR MEMORY DEVICE

(71) Applicant: KABUSHIKI KAISHA TOSHIBA, Minato-ku (JP)

(72) Inventors: Hiroyuki KAGA, Kanagawa-ken (JP); Masahiro Yoshihara, Kanagawa-ken (JP); Naofumi Abiko, Kanagawa-ken (JP); Yoshikazu Harada, Kanagawa-ken (JP)

(73) Assignee: KABUSHIKI KAISHA TOSHIBA, Minato-ku (JP)

(21) Appl. No.: 14/021,272

(22) Filed: Sep. 9, 2013

(30) Foreign Application Priority Data
Mar. 15, 2013 (JP) 2013-054237

(51) Int. Cl. G11C 16/26

(52) U.S. Cl. CPC G11C 16/26
USPC 365/185.21

(57) ABSTRACT

According to one embodiment, a non-volatile semiconductor memory device includes a memory cell array and a sense amplifier. The memory cell array includes a plurality of memory cell transistors. The sense amplifier reads data held in the memory cell transistors. The sense amplifier writes data to the memory cell transistors. The sense amplifier includes a first sense unit, a first operational unit, a second sense unit, and a second operational unit. The first sense unit includes a first sub-amplifier group and a first switch group. The second sense unit includes a second sub-amplifier group and a second switch group. The first sub-amplifier group is electrically connected to a first data bus. The second sub-amplifier group is electrically connected to a second data bus. The first operational unit is electrically connected to the first data bus and the second data bus.

### CROSS REFERENCE TO RELATED APPLICATION

This application is based upon and claims the benefit of priority from the prior Japanese Patent Application No. 2013-054237, filed on Mar. 15, 2013, the entire contents of which are incorporated herein by reference.

### FIELD

Embodiments described herein relate to a non-volatile semiconductor memory device.

### BACKGROUND

A NAND-type flash memory is provided with memory cell transistors arranged in matrix, a sense amplifier which executes processing such as reading data held in the memory cell transistors and writing data to the memory cell transistors, and the like.

### BRIEF DESCRIPTION OF THE DRAWINGS

FIG. 1 is a block diagram showing a non-volatile semiconductor memory device according to a first embodiment;

FIGS. 2(a) and 2(b) are each a diagram showing a sense amplifier according to the first embodiment, FIG. 2(a) showing the configuration of the sense amplifier, FIG. 2(b) being a circuit diagram in which region A is enlarged;

FIG. 3 is a circuit diagram showing an operational unit according to the first embodiment;

FIG. 4 is a diagram showing an operation performed to check the threshold voltage distributions of adjacent memory cell transistors according to the first embodiment;

FIG. 5 is a diagram showing the behavior of the operational unit according to the first embodiment;

FIGS. 6(a) to 6(d) are diagrams showing influence by the adjacent memory transistors according to the first embodiment, FIG. 6(a) showing memory cell transistors, FIGS. 6(b) and 6(c) each showing a threshold voltage distribution of level “C”, FIG. 6(d) showing a threshold voltage distribution corrected to level “N”;

FIG. 7 shows how an operation is performed to check the adjacent memory cell transistors according to the first embodiment;

FIG. 8 is a diagram showing how the operational unit performs an operation according to the first embodiment;

FIG. 9 is a timing chart showing the behavior of each signal according to the first embodiment;

FIG. 10 is an enlarged circuit diagram of a sense amplifier according to a modification of the first embodiment;

FIG. 11 shows how an operation is performed to check adjacent memory cell transistors according to the modification of the first embodiment; and

FIG. 12 shows how an operation is performed to check adjacent memory cell transistors according to the modification of the first embodiment.

### DETAILED DESCRIPTION

According to one embodiment, a non-volatile semiconductor memory device includes a memory cell array and a sense amplifier. The memory cell array includes a plurality of memory cell transistors. The sense amplifier reads data held in the memory cell transistors. The sense amplifier writes data to the memory cell transistors. The sense amplifier includes a first sense unit, a first operational unit, a second sense unit, and a second operational unit. The first sense unit includes a first sub-amplifier group and a first switch group. The second sense unit includes a second sub-amplifier group and a second switch group. The first sub-amplifier group is electrically connected to a first data bus. The second sub-amplifier group is electrically connected to a second data bus. The first operational unit is electrically connected to the first data bus and the second data bus.

Hereinafter, a plurality of embodiments are further described in reference to the drawings. In the drawings, the same reference signs are attached to the same or similar portions.

A non-volatile semiconductor memory device 1 according to a first embodiment will be described with reference to the drawings. FIG. 1 is a block diagram showing the non-volatile semiconductor memory device. In the embodiment, a NAND-type flash memory is described as an example of the non-volatile semiconductor memory device 1.

In the non-volatile semiconductor memory device 1 of the embodiment, in order to decrease influence on data to be written to a certain memory cell transistor MC by data held in memory cell transistors MC electrically connected to bit lines adjacent to that for the certain memory cell transistor MC (adjacent memory cell transistors), the data held in the adjacent memory cell transistors MC are checked in advance. This improves the behavioral reliability for the non-volatile semiconductor memory device 1.

As shown in FIG. 1, the non-volatile semiconductor memory device 1 includes a memory cell array 2, a row decoder 3, a sense amplifier 4, a control unit 5, and a voltage generation circuit 6.

Data and signals are received on one another between a host and a memory controller 100. Data and signals are received on one another between the memory controller 100 and the non-volatile semiconductor memory device 1.

The memory controller 100 generates various commands to control the operations of the non-volatile semiconductor memory device 1, an address, and data, and outputs them to the non-volatile semiconductor memory device 1.

The configuration of the memory cell array 2 is described.

The memory cell array 2 has blocks BLK0 to BLKs (where s is a natural number). The blocks BLK0 to BLKs each include select transistors ST1 (first select transistors), NAND strings 10, and select transistors ST2 (second select transistors). In each NAND string 10, multiple non-volatile memory cell transistors MC are connected in series.

Each memory cell transistor MC can holds data having two values or more. The memory cell transistor MC is, for example, an n-channel MOS transistor having an FG structure which includes a floating gate (charge conductive layer) formed on a p-type semiconductor substrate with a gate insulating film interposed in between and a control gate formed on the floating gate with an inter-gate insulating film interposed in between. The memory cell transistor MC may be a MONOS-type n-channel MOS transistor. The MONOS type is a structure having a charge accumulation layer (e.g., an insulating film) formed on a semiconductor substrate with a gate insulating film interposed in between, an insulating film (referred to as a block layer below) being formed on the charge accumulation layer and having a higher permittivity than the charge accumulation layer, and a control gate formed on the block layer.

The memory cell transistor MC is electrically connected at a control gate to a word line, is electrically connected at a drain to a bit line, and is electrically connected at a source to a source line. A MOS transistor is also referred to as a MOSFET (Metal Oxide Semiconductor Field Effect Transistor). Herein, sixty-four memory cell transistors MC are provided for each NAND string 10. However, the number of the memory cell transistors MC may be 128, 256, 512, or the like, and is not limited.

Adjacent ones of the memory cell transistors MC share the source and the drain (in a direction parallel to the bit lines in FIG. 1). The memory cell transistors MC are arranged between the select transistor ST1 and the select transistor ST2 so that current paths may be connected in series. A drain region of one end side of the memory cell transistors MC connected in series is connected to a source region of the select transistor ST1, and a source region of the other end side of the memory cell transistor MC is connected to a drain region of the select transistor ST2. The select transistor ST1 and the select transistor ST2 are n-channel MOS transistors.

The control gates of the memory cell transistors MC on the same row are connected to a common one of word lines WL0 to WL63. The gates of the select transistors ST1 on the same row are connected to a common select gate line SGD1. The gates of the select transistors ST2 on the same row are connected to a common select gate line SGD2. For the sake of brevity, the word lines WL0 to WL63 may be referred to simply as word lines WL hereinbelow when no discrimination is necessary. The drains of the select transistors ST1 on the same row in the memory cell array 2 are connected to a common one of bit lines BL0 to BLn (where n is a natural number). The bit lines BL0 to BLn may be referred to simply as bit lines BL hereinbelow when no discrimination is necessary. The sources of the select transistors ST2 on the same row in the memory cell array 2 are connected to a common source line SL.

Data is written collectively to the multiple memory cell transistors MC connected to the same word line WL, and this unit is called a page. Data is erased collectively from the multiple memory cell transistors MC on a block BLK basis.

Each memory cell transistor MC holds data on any one of four values. The four values are called, from one having the lowest threshold voltage, level “E”, level “A”, level “B”, and level “C”, for example. Level “E” is referred to as an erased state in which no charge reaches the charge accumulation layer. Then, as more charges are accumulated in the charge accumulation layer, the threshold voltage increases sequentially from level “A” to level “B” and from level “B” to level “C”.

The structure of the memory cell array 2 is described for example in U.S. patent application Ser. No. 12/407,403 titled “THREE DIMENSIONAL STACKED NONVOLATILE SEMICONDUCTOR MEMORY” and filed on Mar. 19, 2009, U.S. patent application Ser. No. 12/406,524 titled “THREE DIMENSIONAL STACKED NONVOLATILE SEMICONDUCTOR MEMORY” and filed on Mar. 18, 2009, U.S. patent application Ser. No. 12/679,991 titled “NON-VOLATILE SEMICONDUCTOR STRAGE DEVICE AND METHOD OF MANUFACTURING THE SAME” and filed on Mar. 25, 2010, and U.S. patent application Ser. No. 12/532,030 titled “SEMICONDUCTOR MEMORY AND METHOD FOR MANUFACTURING SAME” and filed on Mar. 23, 2009. These patent applications are hereby incorporated by reference in their entirety.

The configuration of peripheral circuitry is described.

The row decoder 3 is connected to the multiple word lines WL, and selects and drives the word line WL when data is to be read, written, or erased.

The sense amplifier 4 is connected to the multiple bit lines BL, and controls voltage for the bit lines BL when data is to be read, written, or erased. The sense amplifier 4 detects the potentials of the bit lines BL for example, when data held in the memory cell transistors MC is to be read. The invention is not limited to the above case. For example, the sense amplifier 4 may detect a cell current when data held in the memory cell transistors MC is to be read. In writing data, the sense amplifier 4 applies voltage to the bit line BL, the voltage being in accordance with the data to be written.

Based on a command CMD and an external control signal supplied from a host (not shown) according to an operation mode, the control unit 5 generates a control signal to control the sequence of writing and erasing data and a control signal to control reading of data. These control signals are transmitted to the row decoder 3, the sense amplifier 4, the voltage generation circuit 6, and the like.

In the embodiment, in writing of data, the control unit 5 uses these control signals to check data stored in a latch DL (e.g., a UDL (to be described later)) of the sense amplifier 4. When the data stored in the latch DL is “1”, in writing of data, a threshold voltage for the corresponding memory transistor MC is set to be lower than a desired value.

The control unit 5 does not necessarily have to be placed in the non-volatile semiconductor memory device 1. The control unit 5 may be placed in a semiconductor device different from the non-volatile semiconductor memory device 1, or may be placed in the host.

The voltage generation circuit 6 generates a read voltage (Vread, VCGR), a write voltage (VPGM), a verify voltage (VCGR_CV), and an erase voltage (VERA). The voltage generation circuit 6 generates voltage necessary for each operation of the memory cell array 2, the row decoder 3, and the sense amplifier 4.

The configuration of the sense amplifier 4 is described.

FIG. 2(a) and (b) are diagrams showing the sense amplifier 4. FIG. 2(a) shows the configuration of the sense amplifier 4, and FIG. 2(b) shows a circuit diagram in which region A is enlarged.

As shown in FIG. 2(a), the sense amplifier 4 includes multiple sense units SAU. The following description focuses on the sense units SAU in region A.

As shown in FIG. 2(b), the sense amplifier 4 includes a sense unit SAU_(m−1) (third sense unit), a sense unit SAU_m (first sense unit), and a sense unit SAU_(m+1) (second sense unit) which are arranged in parallel in a first direction. The sense unit SAU_(m−1), the sense unit SAU_m, and the sense unit SAU_(m+1) each have pattern A. The sense units SAU_{—}0 to SAU_m are referred to simply as sense units SAU when no discrimination is necessary. Each sense unit SAU includes sixteen sub-amplifiers SSA0 to SSA15. The sub-amplifiers SSA0 to SSA15 are referred to simply as sub-amplifiers SSA when no discrimination is necessary.

The sub-amplifiers SSA read data held in the memory cell transistors MC (referred to as held data below) or write data to the memory cell transistors MC via the corresponding bit lines BL. Each sense unit SAU is electrically connected to sixteen bit lines BL extending in a second direction.

For example, the sense unit SAU_{—}0 is electrically connected to the bit lines BL0 to BL15, the sense unit SAU_{—}1 is electrically connected to the bit lines BL16 to BL31, . . . , and the sense unit SAU_m is electrically connected to the bit lines BL16m to BL(16m+15) (where m is an integer of zero or larger).

FIG. 2(b) shows specific connection between the bit lines BL and the sub-amplifiers SSA. For example, in the sense unit SAU_m, the sub-amplifier SSA0 is connected to the bit line BL16m, the sub-amplifier SSA1 is connected to the bit line BL(16m+1), . . . , and the sub-amplifier SSA15 is connected to the bit line BL(16m+15).

The sub-amplifiers SSA0 to SSA15 (a first sub-amplifier group) of the sense unit SAU_m are connected to a common data bus DBUSm (first data bus) via corresponding switches SW0 to SW15 (a first switch group), respectively. The sub-amplifiers SSA0 to SSA15 (a second sub-amplifier group) of the sense unit SAU_(m+1) are connected to a common data bus DBUS(m+1)(second data bus) via corresponding switches SW0 to SW15 (a second switch group), respectively. The sub-amplifiers SSA0 to SSA15 (a third sub-amplifier group) of the sense unit SAU_(m−1) are connected to a common data bus DBUS(m−1) (third data bus) via corresponding switches SW0 to SW15 (a third switch group), respectively.

Each of the sub-amplifiers SSA0 to SSA15 includes either a first latch (referred to as an SDL below) or a second latch (referred to as a UDL below). For example, the sub-amplifier SSA6 is provided with the SDL, the sub-amplifier SSA7 is provided with the UDL, and the sub-amplifier SSA8 is provided with the SDL. The SDL holds write data or read data. In the embodiment, for example, the UDL holds an operation result transferred from an operational unit NDL to be described later.

The SDL provided to each sub-amplifier SSA has one end connected to one end of a MOS transistor Tr1 connected to a local bus LBUS. The MOS transistor Tr1 is turned on and off according to a signal STL inputted to a gate of the MOS transistor Tr1. The UDL provided to the sub-amplifier SSA has one end connected to one end of a MOS transistor Tr2 connected to a local bus LBUS. The MOS transistor Tr2 is turned on and off according to a signal UTL inputted to a gate of the MOS transistor Tr2.

The sense amplifier 4 includes data latch (referred to as operational units NDL0 to NDLm below). The operational units NDL0 to NDLm are correspondingly placed for the respective sense units SAU_{—}0 to SAU_m. Each of the operational units NDL0 to NDLm is connected to a corresponding one of the sense units SAU_{—}0 to SAU_m via a corresponding one of switches NDSW0 to NDSWm and the corresponding data bus DBUS. Specifically, the operational unit NDLm−1 (third operational unit) is connected to the data bus DBUS(m−1) (third data bus) via the switch NDSW(m−1). The operational unit NDLm (first operational unit) is connected to the data bus DBUSm (first data bus) via the switch NDSWm (fourth switch). The operational unit NDLm+1 (second operational unit) is connected to the data bus DBUS(m+1) (second data bus) via the switch NDSW(m+1). The switches NDSW0 to NDSWm are MOS transistors.

The operational units NDL0 to NDLm are each connected to an adjacent data bus DBUS via a corresponding one of switches SW0_NDL2 to SWm_NDL2. Specifically, the operational unit NDLm−1 is connected to the data bus DBUSm (first data bus) via the switch SW(m−1)_NDL2. The operational unit NDLm is connected to the data bus DBUS(m+1) (second data bus) via the switch SWm_NDL2 (fifth switch). Each operational unit NDL performs an operation (e.g., an AND operation or an OR operation) on data held in the sub-amplifiers SSA. The switches SW0_NDL2 to SWm_NDL2 are MOS transistors. Switches SW0_NDL3 to SWm_NDL3(sixth switch) are MOS transistors.

Operations performed by the operational units NDL are described by taking the operational unit NDLm as an example.

As an example, the following describes a case of storing an operation result in the UDL of the sub-amplifier SSA7 of the sense unit SAU_m. In this case, in the operational unit NDLm, an operation result for data held in the sub-amplifiers SSA6 and SSA8 of the sense unit SAU_m is stored.

For a certain sub-amplifier SSA being focused on, write data in sub-amplifiers SSA which correspond to memory cell transistors MC adjacent, in the first direction, to a memory cell transistor MC corresponding to the certain sub-amplifier (called a focused-on memory cell transistor MC) are used. This is because the certain sub-amplifier SSA may be influenced by threshold voltage distributions of the memory cell transistors MC adjacent to the focused-on memory cell transistor MC in the first direction.

In a case where the focused-on memory cell transistor MC has a low threshold voltage distribution (e.g., level “A”) but the memory cell transistors MC adjacent to the focused-on memory cell transistor MC have high threshold voltage distributions (e.g., level “C”), the low threshold voltage distribution tends to shift to the high threshold voltage level by being influenced by the threshold voltage distributions on the both sides.

To prevent the influence, before writing data, the control unit 5 needs to know data to be written to the memory cell transistors MC adjacent in the first direction based on an operation result. In the case where the data to be written is known, the threshold voltage distribution for writing the data can be set to be low to avoid the influence described above, and to therefore enhance data reliability.

How to select data used to perform an operation is the same for all the sense units SAU. Generally, an operation is performed on data held in a sub-amplifier SSAn−1 (where n is a positive integer) and data held in a sub-amplifier SSA(n+1). Note that there is a case where an arrangement order of the sub-amplifiers SSA, which corresponds to an arrangement order of the bit lines, is different for each data bus DBUS (for every 16 BL). The method for performing an operation for such a case will be descried later using a modification.

The operational unit NDL will be described in detail. FIG. 3 is a circuit diagram showing the operational unit NDL. In FIG. 3, the operational unit NDLm is used as an example of the operational unit NDL. As shown in FIG. 3, the operational unit NDLm (first operational unit) includes a latch LAT (third latch), a switch SW1 (sixth switch), and a switch SW2 (eighth switch). The latch LAT is provided with ring-shaped inverters INV1 and INV2. The switches SW1 and SW2 are MOS transistors.

The data held in the latch LAT is data on an output end of the inverter INV1 (or an input end of the inverter INV2), and is called DATA below. Thus, /DATA (where “/” indicates inversion) is inputted to an input end of the inverter INV1. A wiring connecting the output end of the inverter INV1 and the input end of the inverter INV2 is called a line A, and the other wiring is called a line B.

The switch SWm_NDL2 has one end connected to the data bus DBUS(m+1) and the other end connected to a node N1 and the line A. The switch SWm_NDL3 has one end connected to the data bus DBUS(m−1) and the other end connected to the node N1 and the line A. The switch NDSWm has one end connected to the data bus DBUSm and the other end connected to the node N1. The switch NDSWm is turned on when an operation result is transferred from the latch LAT to the UDL.

The switch SW1 has one end connected to the node N1 and a control terminal connected to the data bus DBUSm. The switch SW1 is turned on and off according to a voltage at the data bus DBUSm. The switch SW2 has one end connected to the other end of the switch SW1, has a control terminal to which a signal NTL (first control signal) is inputted, and the other end to which a ground voltage Vss is applied. The switch SW2 is turned on and off according to a voltage of the signal NTL.

When data held in each sub-amplifier SSA is of level “C”, the latch LAT holds “1” as a result of an operation performed on the data (the line A=the “H” level). This will be described more later.

A detail description will be given of a method of performing an operation. FIG. 4 is a diagram showing how an operation is performed to check the threshold voltage distributions of adjacent memory cell transistors MC. As an example, the operation method (part 1) shown in FIG. 4 is for a case of storing an operation result in the UDL of the sub-amplifier SSA7. FIG. 4 is a circuit diagram focusing on the sense unit SAU_m in FIG. 2, and is a conceptual diagram to illustrate how an operation is performed.

In the operation described below, the control unit 5 turns on and off each signal. Specifically, the control unit 5 controls the signal level of each signal STL and controls turning on and off of the switches SW0 to SW15. In the description given below, only the sense unit SAU_m is shown, but actually, the control unit 5 simultaneously controls the signal levels of the signals STL for the sub-amplifiers SSA arranged for the respective sense units SAU and located on the same row and controls the turning on and off of the switches SW.

Herein, for example, the control unit 5 simultaneously controls the signal levels of the signals STL for all the sub-amplifiers SSA7 and controls the turning on and off of the switches SW7.

As shown in FIG. 4, first, the control unit 5 transfers write data WD6 from the sub-amplifier SSA6 in the sense unit SAU_m to the operational unit NDLm (Step S1).

Next, the control unit 5 transfers write data WD8 held in the sub-amplifier SSA8 to the operational unit NDLm (Step S2).

Subsequently, the operational unit NDLm performs an AND operation through Steps S1 and S2 above, and holds a result of the AND operation (Step S3).

Then, the control unit 5 transfers the operation result (WD6∩WD8) obtained in Step S3 to the UDL of the focused-on sub-amplifier SSA7 (Step S4).

Although the sub-amplifier SSA7 is being focused on here, the operation is performed similarly for all the other sub-amplifiers SSA, as well. Thus, when all the operations are done, an operation result is stored in all the UDLs of the sub-amplifiers SSA. The control unit 5 performs an appropriate data write process based on the operation results in the UDLs.

A description will be given of an operation performed by the operational unit NDLm in Steps 1 and 2 above.

FIG. 5 is a diagram showing an operation performed by the operational unit NDLm. Here, it is assumed that the write data WD6 has any level but level “C”, and the write data WD8 has level “C”, where level “C” is data “1”, and any level but level “C” is “0”.

As shown in FIG. 5, in Step S1 described above, data “1” being an inversion of the write data WD6=0 is inputted to the gate of the switch SW1 via the data bus DBUSm. As a result, the switch SW1 is turned on (Step S10).

At the same time, by being set to level “H”, the signal NTL turns the switch SW2 on. As a result, a current I1 flows from the latch LAT toward the ground voltage Vss, making the node N1 have the ground voltage Vss (Step S11).

Consequently, the voltage at the line A shifts to the level “L” (data “0” in FIG. 5), and a result of the AND operation on the write data WD6 and the write data WD8 is held (Step S12).

In Step S12 above, data “0” being an inversion of the write data WD8=1 is inputted to the gate of the switch SW1 from the data bus DBUSm. As a result, the switch SW1 is turned off (Step S13).

Even when the switch SW2 is turned on at the same time by setting the signal NTL to level “H”, the current I1 does not flow because the switch SW1 is off. As a result, the voltage at the node N1 is maintained (Step S14).

Thus, the voltage level of the line A is maintained at “L” (data “0” in FIG. 5) (Step S15).

Thereafter, a signal of level “H” is inputted to the gate of the switch NDSWm to turn the switch NDSWm on. Consequently, the operation result is transferred to the UDL of the sub-amplifier SSA7 via the data bus DBUSm.

A description will be given of a concept where, based on the operation result obtained above, the control unit 5 recognizes the threshold voltage distributions of the memory cell transistors MC and corrects the threshold voltage distribution of the focused-on memory cell transistor MC.

FIGS. 6(a) to 6(d) are diagrams illustrating influence by adjacent memory transistors in a case where the operation result transferred in Step S4 above is “1”. FIG. 6(a) shows the memory cell transistor MC6 connected to the bit line BL(16m+6), the memory cell transistor MC7 connected to the bit line BL(16m+7), and the memory cell transistor MC8 connected to the bit line BL (16m+8). FIGS. 6(b) and 6(c) show threshold voltage distributions of the memory cell transistors MC6 and MC8, respectively, of level “C”. FIG. 6(d) shows a threshold voltage distribution corrected to a level “A′”.

When the operation result transferred in Step S4 above is “1”, the control unit 5 recognizes that data held in the memory cell transistor MC6 and data held in the memory transistor MC8 both have the level “C”. The threshold voltage distributions in such a case are as shown in FIGS. 6(b) and 6(c).

In such a case, the threshold voltage distribution of the memory cell transistor MC7 sandwiched by the memory cell transistors MC6 and MC8 is influenced by the memory cell transistors MC6 and MC8.

Thus, the threshold voltage distribution of the memory cell transistor MC7 can shift to the positive side. To avoid the shift, in writing data, the threshold voltage distribution is shifted, in advance, to a threshold voltage distribution lower than a predetermined threshold voltage distribution.

Specifically, as shown in FIG. 6(d), the control unit 5 shifts, in advance, the threshold voltage distribution of the memory cell transistor MC7 to a distribution (level “A” in FIG. 6(d)) lower than a desired distribution (level “A” in FIG. 6(d)). By applying predetermined voltage to the bit line BL and the word line WL, the control unit 5 shifts and thus corrects the threshold voltage distribution to a distribution lower than a desired distribution.

The details of the operation method will be described.

FIG. 7 shows how an operation is performed to check the adjacent memory cell transistors, and shows a method (part 2) of performing an operation for a case of storing an operation result in the UDL of, for example, the sub-amplifier SSA15. In such a case, an operation is performed on data from the sub-amplifier SSA14 of the sense unit SAU_m and data from the sub-amplifier SSA0 of the sense unit SAU_(m+1), and a result of the operation is stored in the UDL of the sub-amplifier SSA15.

As shown in FIG. 7, first, the control unit 5 transfers write data WD0 held in the sub-amplifier SSA0 of the sense unit SAU_(m+1) to the operational unit NDLm (Step S20).

Next, the control unit 5 transfers write data WD14 held in the sub-amplifier SSA14 of the sense unit SAU_m to the operational unit NDLm (Step S21).

As a result of Steps S20 and S21 above, the operational unit NDLm performs an AND operation and holds a result of the AND operation (Step S22).

Thereafter, the control unit 5 transfers the operation result (WD0∩WD14) in Step S22 above to the UDL of the sub-amplifier SSA15 in the sense unit SAU_m currently being focused on (Step S23).

The behavior of the operational unit NDL will be described. In the following description, the operational unit NDLm is used as an example.

FIG. 8 is a diagram showing how the operational unit NDLm performs an operation. Here, write data WD0=data “1” (level “H”), and write data WD14=data “1” (level “C”).

As shown in FIG. 8, first, the control unit 5 transfers write data WD0=data “1” (level “H”) via the switch SWm_NDL2 in Step S20 described above. As a result, the voltage at the line A becomes data “1” (level “H”). In this process, the latch LAT holds data “1” (level “H”) (Step S30).

Next, the control unit 5 inputs the write data WD14=data “1” from the sub-amplifier SSA14 into the gate of the switch SW1 via the data bus DBUSm in Step S21 described above. Simultaneously, the control unit 5 inputs a signal NTL of level “H” into the gate of the switch SW2 to turn on the switch SW2. Since the switches SW1 and SW2 are both on, the current I1 flows, making the node N1 have level “L” (Step S31).

Subsequently, since the voltage at the line A is at the level “L” (data “0” in FIG. 8) in Step S31 above, a result of an AND operation by the operational unit NDLm is held. Thus, the latch LAT holds data “0” (Step S32).

Thereafter, the control unit 5 inputs a voltage of level “H” into the gate of the switch NDSWm to turn the switch NDSWm on, and transfers the operation result to the UDL of the sub-amplifier SSA15 of the sense unit SAU_m via the data bus DBUSm.

A description is given of change in the voltage of each signal in the operation process in FIG. 4 described above.

FIG. 9 is a timing chart showing the behavior of each signal in the process of the operation in FIG. 4. FIG. 9 shows change in a signal STL6, a signal STL8, a signal UTL 7, a signal NTL, and a signal inputted to the gate of the switch NDSWm, where the signal STL6 is a signal STL for the sub-amplifier SSA6, the signal STL8 is a signal STL for the sub-amplifier SSA8, and the signal UTL7 is a signal UTL for the sub-amplifier SSA7. Although not shown, other signals STL and UTL are set to level “L”.

FIG. 9 corresponds to the operation process in FIG. 4, and shows the behaviors of the signals in storing the operation result (WD6∩WD8) on data in the sub-amplifiers SSA6 and SSA8 of the sense unit SAU_m, in the UDL of the sub-amplifier SSA7.

As shown in FIG. 9, at time t0, the control unit 5 changes the levels of the signal STL6 and the signal NTL from level “L” to level “H”. As a result, write data is transferred from the SDL of the sub-amplifier SSA6 of the sense unit SAU_m to the operational unit NDLm. After the write data is transferred, the control unit 5 changes the levels of the signal STL6 and the signal NTL from level “H” to level “L” at time t1.

Next, the control unit 5 changes the levels of the signal STL8 and the signal NTL from level “L” to level “H” at time t2. As a result, write data is transferred from the SDL of the sub-amplifier SSA8 of the sense unit SAU_m to the operational unit NDLm. After the write data is transferred, the control unit 5 changes the levels of the signal STL8 and the signal NTL from level “H” to level “L” at time t3. At the same time, the operational unit NDLm performs an AND operation on the write data WD6 and the write data WD8, and stores a result of the AND operation.

Subsequently, the control unit 5 changes the levels of the signal UTL7 and the signal inputted to the control terminal of the switch NDSWm from level “L” to level “H” at time t4. As a result, the operation result is transferred from the operational unit NDLm to the UDL of the sub-amplifier SSA7 of the sense unit SAU_m and stored in the UDL. After the operation result is stored, the control unit 5 changes the levels of the signal UTL7 and the signal inputted to the control terminal of the switch NDSWm from level “H” to level “L” at time t5.

The voltage level of the switch SW (see FIG. 4) is changed at the same time as the corresponding signal STL or UTL. For example, focusing on the sub-amplifier SSA6, the control unit 5 turns on or off the switch SW6 at the same time that the signal STL is changed in level.

Although the change in the signal STL6, the signal STL8, the signal UTL7, the signal NTL, and the signal inputted to the gate of the switch NDSWm are shown here to correspond to FIG. 4, the above process is performed for every one of the sub-amplifiers SSA0 to SSA15.

The operation may be performed in order from the sub-amplifiers SSA0 to SSA15, or may be performed for the sub-amplifiers SSA1 to SSA14 first, and then for the sub-amplifiers SSA0 and SSA15, or may be performed in any other order. The order of performing the operation is not limited as long as a result of an AND operation is stored in the operational unit NDL, and thereafter the result is transferred to the UDL of a focused-on sub-amplifier SSA. The same applies to a case of performing an OR operation to be described later.

A description will be given of effects of the non-volatile semiconductor memory device 1 according to the embodiment.

The non-volatile semiconductor memory device 1 can offer the following effects.

Specifically, the threshold voltage distribution of a focused-on memory cell transistor MC can be shifted to a desired threshold voltage distribution taking into consideration the influence by the threshold voltage distributions of the memory cell transistors MC adjacent to the focused-on memory cell transistor MC in the first direction. Thus, the behavioral reliability of the non-volatile semiconductor memory device 1 can be improved.

The sense amplifier 4 includes the operational units NDL each being connected to its own data bus DBUS and also to the data buss DBUS of the sense units SAU adjacent on both sides. Thus, control can be performed taking into consideration the influence by the threshold voltage distributions of the memory cell transistors MC adjacent in the first direction.

As described above, a focused-on memory cell transistor MC tends to be influenced by the threshold voltage distributions of memory cell transistors MC adjacent to the focused-on memory cell transistor MC in the first direction. For example, suppose that the threshold voltage distribution of a certain memory cell transistor MC is intended to be shifted to the level “A”. In the above case, when the threshold voltage distributions of the adjacent memory cell transistors MC have level “C” which is higher than level “A”, the threshold voltage distribution of the memory cell transistor MC of level “A” is raised toward “C”.

The above tendency is noticeable particularly when the threshold voltage distribution of both of the memory cell transistors adjacent on both sides of the certain memory transistor MC is level “C”. For example, against the intention of shifting the threshold voltage distribution of the certain memory transistor MC to level “A”, the threshold voltage distribution might be raised to the level “B”. In a memory cell retaining multi-value data whose threshold voltage distribution has a narrow interval, the above possibility is more noticeable, and a possibility of erroneous reading is high.

However, in the non-volatile semiconductor memory device 1 of the embodiment, the control unit 5 checks data stored in the UDL of a focused-on memory cell transistor MC to check, in advance, the threshold voltage distributions (write data) of memory cell transistors MC adjacent to the focused-on memory cell transistor MC on both sides.

Thus, for example, when the data to be written to the adjacent memory cell transistors MC on both sides are level “C”, the control unit 5 shifts the threshold voltage distribution of the middle memory cell transistor MC to a threshold voltage distribution somewhat lower than a desired threshold voltage distribution. Thereby, the data write reliability can be improved.

The threshold voltage distribution of the middle memory cell transistor MC may be shifted to a threshold voltage distribution somewhat lower than a predetermined threshold voltage distribution also when only one of the memory cell transistors MC adjacent on both sides is level “C”. In the above case, the operational unit NDL performs an OR operation.

When one of two data sets acquired from the sub amplifiers SSA is data “0” (e.g., a combination of data “1” and data “0”), an AND operation results in data “0”. Thus, it cannot be judged whether both of the memory cell transistors MC are data “0” or one of them is data “0”.

By performing an OR operation, it can be found out that any one of the data sets is data “1” when a result of the OR operation is data “1”.

In an OR operation, a proper operation is made possible by appropriately inverting data transferred to the operational unit NDL or the UDL circuit.

A description is given of a non-volatile semiconductor memory device according to a modification of the embodiment. The non-volatile semiconductor memory device according to the modification is different from that of the embodiment in the arrangement of the sub-amplifiers SSA constituting each sense unit SAU. For this reason, the order of performing an operation is different.

FIG. 10 is an enlarged circuit diagram showing a sense amplifier 4a of the non-volatile semiconductor memory device according to the modification. As shown in FIG. 10, the sense amplifier 4a includes a sense unit SAU_(m−1) of pattern A, a sense unit SAU_m of pattern B, and a sense unit SAU_(m+1) of pattern A, for example. The sense units SAU_(m−1) and SAU_(m+1) of pattern A have the same configuration as those of the sense amplifier 4 of the embodiment, and therefore are not described again here.

The configuration of the sense unit SAU_m of pattern B will be described. The sense unit SAU_m of pattern B is provided with, from down to up in FIG. 10, the sub-amplifiers SSA0, . . . , SSA8, . . . , SSA6, SSA7, SSA4, . . . , SSA15. In the modification, at a position where the sub-amplifier SSA8 is placed in the embodiment, the sub-amplifier SSA4 is placed instead. In the above case, there is a need to change the arrangement of the bit lines BL, too, because the bit line BL(16m+4) cannot be extended down like in pattern A.

Specifically, the bit line BL(16m+4) is detoured to the right side of the bit line BL(16+6) and the bit line BL(16m+7) and connected to the sub-amplifier SSA4. The bit line BL (16m+8) is extended to the original position of the sub-amplifier SSA4.

As described above, in the sense amplifier 4a, the sense unit SAUs of pattern A are placed on both sides of the sense unit SAU of pattern B.

A description is given of a method for performing an operation by the non-volatile semiconductor memory device according to the modification.

FIGS. 11 and 12 show a process of performing an operation to check the adjacent memory cell transistors according to the modification. FIG. 11 shows a method for performing an operation focusing on pattern A, and shows Steps S40 to S42.

FIG. 12 shows a method for performing an operation focusing on pattern B, and shows Steps S43 to S45. In FIGS. 11 and 12, an operation result is stored in the UDL of each sub-amplifier SSA7.

As shown in FIG. 11, first, the control unit 5 transfers write data WD6 from the sub-amplifier SSA6 of the sense unit SAU_(m−1) of pattern A to the operational unit NDLm−1, transfers write data WD6 from the sub-amplifier SSA6 of the sense unit SAU_m of pattern B to the operational unit NDLm, and transfers write data WD6 from the sub-amplifier SSA6 of the sense unit SAU_(m+1) of pattern A to the operational unit NDLm+1. Each of the operational unit NDLm−1, the operational unit NDLm, and the operational unit NDLm+1 stores the write data WD6 (Step S40).

Next, for pattern A, the control unit 5 transfers write data WD8 from the sub-amplifier SSA8 of the sense unit SAU_(m−1) of pattern A to the operational unit NDLm−1, and transfers write data WD8 from the sub-amplifier SSA8 of the sense unit SAU_(m+1) of pattern A to the operational unit NDLm+1. The operational units NDLm−1 and NDLm+1 of pattern A each performs an operation on the write data WD6 and the write data WD8, and stores a result of the operation (Step S41).

In this step, write data WD4 is transferred from the sub-amplifier SSA4 of the sense unit SAU_(m+1) of pattern B because the control unit 5 simultaneously changes the levels of signals corresponding to the sub-amplifiers SSA located on the same row.

However, since the control unit 5 turns off the switch DNSWm of pattern B which connects the operational unit NDL and the data bus DBUS, the write data WD4 is not stored in the operational unit NDLm of pattern B, and only the write data WD6 is stored.

Subsequently, for pattern A, the operation result (WD6∩WD8) is transferred from the operational unit NDL to the UDL of the sub-amplifier SSA7, and for pattern B, only the write data WD6 is transferred from the operational unit NDL to the UDL of the sub-amplifier SSA7. Finally, the control unit 5 resets the operational units NDL to make them stand by for the next data operation (Step S42).

As shown in FIG. 12, for pattern B, the control unit 5 transfers write data WD8 in the sub-amplifier SSA8 of the sense unit SAU_m to the operational unit NDLm. The operational unit NDLm of pattern B stores the write data WD8 (Step S43).

In this step, in pattern A, the write data WD4 in the sub-amplifier SSA4 of the sense unit SAU_(m−1) is outputted to the data bus DBUS(m−1), and the write data WD4 in the sub-amplifier SSA4 of the sense unit SAU_(m+1) is outputted to the data bus DBUS(m+1). However, since the control unit 5 has turned off the switch NDSW(m−1) connecting between the operational unit NDLm−1 and the data bus DBUS(m−1) and the switch NDSW(m+1) connecting between the operational unit NDLm+1 and the data bus DBUS(m+1), the operational unit NDLm−1 and the operational unit NDLm+1 of pattern A maintain the reset state.

Then, the control unit 5 transfers data (the operation result (WD6∩WD8)) in the UDL of the sub-amplifier SSA7 of the sense unit SAU_(m−1) of pattern A to the operational unit NDLm−1, transfers data (the write data WD6) in the UDL of the sub-amplifier SSA7 of the sense unit SAU_m of pattern B to the operational unit NDLm, and transfers data (the operation result (WD6∩WD8)) in the UDL of the sub-amplifier SSA7 of the sense unit SAU_(m+1) of pattern A to the operational unit NDLm+1. In this process, the operational unit NDLm of pattern B performs an operation on the write data WD8 and the write data WD6 and stores a result of the operation. The operational units NDLm−1 and NDLm+1 of pattern A each store the transferred data (the operation result (WD6∩WD8) (Step S44).

Next, the control unit 5 transfers the operation result obtained by the operational unit NDLm−1 of pattern A to the UDL of the sub-amplifier SSA7 of the sense unit SAU_(m−1), transfers the operation result obtained by the operational unit NDLm of pattern B to the UDL of the sub-amplifier SSA7 of the sense unit SAU_m, and transfers the operation result obtained by the operational unit NDLm+1 of pattern A to the UDL of the sub-amplifier SSA7 of the sense unit SAU_(m+1) (Step S45).

When the arrangement of the adjacent sense units SAU is different, an operation result can be obtained by performing the processes in Steps S40 to S45 described above.

The non-volatile semiconductor memory device according to the modification can offer the same effects as the embodiment. Reasons are described below.

Even when the arrangement of the sub-amplifiers SSA or how the bit lines corresponding to the sub-amplifiers SSA are connected is different from that of the adjacent sense units SAU, such as pattern A and pattern B, a desired operation result can be obtained by appropriately changing the operation process.

Also in the modification, the control unit 5 can check data stored in the UDLs to check, in advance, write data in each of memory cell transistors MC located on both sides of a memory cell transistor MC to which data is to be written.

Thus, the threshold voltage distribution of a focused-on memory cell transistor MC can be controlled according to the data to be written to the adjacent memory cell transistors MC. Thereby, the reliability of write data can be improved.

Furthermore, data transfer may be performed by using a command for a transfer operation output from the memory controller 100.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile semiconductor memory device comprising:
a memory cell array including a plurality of memory cell transistors; and
a sense amplifier to read data held in the memory cell transistors, the sense amplifier to write data to the memory cell transistors, the sense amplifier including a first sense unit, a first operational unit, a second sense unit, and a second operational unit, the first sense unit including a first sub-amplifier group and a first switch group, the second sense unit including a second sub-amplifier group and a second switch group, the first sub-amplifier group being electrically connected to a first data bus, the second sub-amplifier group being electrically connected to a second data bus, and the first operational unit being electrically connected to the first data bus and the second data bus.

2. The device according to claim 1, wherein
the sense amplifier has a third sense unit and a third operational unit,
the third sense unit has a third sub-amplifier group and a third switch group,
the third sub-amplifier group is electrically connected to a third data bus, and
the first operational unit is electrically connected to the third data bus.

3. The device according to claim 1, further comprising:
a control unit configured to perform data transfer operation, wherein
the first sub-amplifier group has a first sub-amplifier, a second sub-amplifier, and a third sub-amplifier,
the first sub-amplifier being connected to a first bit line, the second sub-amplifier being connected to a second bit line, the third sub-amplifier being connected to a third bit line, the second bit line being provided between the first bit line and the third bit line, the control unit transfers data stored in the first sub-amplifier to the first operational unit and transfers data stored in the third sub-amplifier to the first operational unit, the first operational unit performs a first operation on the data from the first sub-amplifier and the data from the third sub-amplifier, and stores a result of the first operation, and the control unit transfers the result of the first operation stored in the first operational unit to the second sub-amplifier.

4. The device according to claim 3, wherein
the first sub-amplifier and the third sub-amplifier each have a first latch, and
the second sub-amplifier has a second latch.

5. The device according to claim 4, wherein
the first sub-amplifier has a first transistor,
the second sub-amplifier has a second transistor,
the third sub-amplifier has a third transistor,
the first transistor has one end connected to the first latch of the first sub-amplifier and the other end side connected to the first data bus,
the second transistor has one end connected to the second latch of the second sub-amplifier and the other end side connected to the first data bus,
the third transistor has one end connected to the first latch of the third sub-amplifier and the other end side connected to the first data bus, and
in the first operation, the control unit
turns on the first transistor, and turns on the third transistor after turning off the first transistor, and
turns on the first switch and the second transistor after turning off the third transistor.

6. The device according to claim 1, further comprising:
a control unit configured to perform data transfer operation, wherein
the first sub-amplifier group has a first sub-amplifier and a second sub-amplifier respectively corresponding to bit lines adjacently arranged,
the second sub-amplifier group includes a third sub-amplifier,
the control unit transfers data stored in the third sub-amplifier to the first operational unit and transfers data stored in the first sub-amplifier to the first operational unit,
the first operational unit performs a second operation on the data from the third sub-amplifier and the data from the first sub-amplifier and stores a result of the second operation, and
the control unit transfers the result of the second operation stored in the first operational unit to the second sub-amplifier.

7. The device according to claim 1, wherein
the first operational unit has a third latch, a seventh switch, and an eighth switch,
the third latch includes first and second inverters, and is connected at an input side to the first data bus via the first switch,
the seventh switch has one end connected to the input side of the third latch and has a control terminal connected to the first data bus, and
the eighth switch has one end connected to the other end of the seventh switch, has a control terminal to which a first control signal is inputted, and has the other end to which a ground voltage is applied.

8. The device according to claim 1, wherein
the first switch group, the second switch group, the fourth switch, and the fifth switch are MOS transistors.

9. The device according to claim 1, wherein
in the memory cell array, a first select transistor, a plurality of memory cell transistors connected in series, and a second select transistor are connected in series,
the first select transistor has one end connected to a bit line and the other end connected to one end of the plurality of memory cell transistors connected in series, and
the second select transistor has one end connected to the other end of the plurality of memory cell transistors connected in series and the other end connected to a source line.

10. The device according to claim 7, wherein
in the operation of the first operational unit,
the seventh switch turns on when the control terminal of the seventh switch is input the data stored in the first sub-amplifier, the eighth switch turns on when the control terminal of the eighth switch is input a first control signal, by on state of the seventh switch and the eighth switch, the third latch has a low level so as to hold the result of the operation stored in the first operational unit, and
the seventh switch turns off when the control terminal of the seventh switch is input the inverted data of the data stored in the first sub-amplifier, the third latch has a low level so as to hold the result of the operation stored in the first operational unit despite on state or off state of the eighth switch.

11. A method of controlling a non-volatile semiconductor memory device including a sense amplifier, wherein
the sense amplifier includes a first sense unit and a first operational unit,
the first sense unit includes first to third sub-amplifiers,
the first operational unit includes a third latch, a seventh switch, and an eighth switch,
the method comprising:
inputting an inverted data of data held in the first sub-amplifier to the control terminal of the seventh switch, turning on the seventh switch;
inputting a control signal with an enable state to the control terminal of the eighth switch when the seventh switch holds on state, turning on the eighth switch, holding a first hold voltage of the third latch;
inputting an inverted data of data held in a second sub-amplifier to the control terminal of the seventh latch, turning off the seventh switch;
inputting the control signal with an enable state or a disable state when the seventh switch holds off state, holding the first hold voltage of the third latch; and
transferring the first hold voltage to the third sub-amplifier provided between the first sub-amplifier and the second sub-amplifier.
